(19) United States
(12) Patent Application Publication
(10) Pub. No.: US 2025/0020695 A1
(43) Pub. Date: Jan. 16, 2025

(54) ROGOWSKI INTEGRATOR KIT AND ROGOWSKI COIL

(71) Applicant: Accuenergy (Canada) Inc., Toronto (CA)

(72) Inventors: Vahid Behjat, Toronto (CA); Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 18/221,400

(22) Filed: Jul. 13, 2023

(51) Int. Cl. G01R 15/18; H02J 13/00

(52) U.S. Cl. CPC G01R 15/181; H02J 13/00002

(57) ABSTRACT

A Rogowski integrator kit, equipped with RJ45 socket, that provides simple installation and protection against Electromagnetic Interference (EMI) and Electrostatic Discharge (ESD). The kit consists of a Rogowski coil that comes with a first RJ45 socket and an electrical integrator that includes a second RJ45 socket. With these features, the Rogowski integrator kit ensures reliable and accurate measurement in a safe and secure manner.

### FIELD OF THE INVENTION

The present disclosure generally relates to a Rogowski coil type sensor.

### BACKGROUND OF THE INVENTION

A Rogowski coil, also known as flexible current transformer, is an instrument used to safely measure alternating current (AC) traveling through a primary conductor such as a cable or busbar in an electrical panel. Through a step-down process, it can be used for metering or protection purposes. As electrical current flows through the conductor it induces a voltage in the coil in proportion to the variation of the conductor's current.

The Rogowski coil has a closing unit that holds the ends of the coil together and connects the output cable to an integrator or intelligent electronic devices (IED). A conventional design and structure of the closing unit provides a housing for soldering the coil output terminals to the out leads and then transmitting the measured signal over twisted pair lead wires. The out-lead wires are soldered to the coil output terminals which is a time-demanding and labour-intensive process. If needed to extend the cable, an extension is spliced on the cable which makes it susceptible to electromagnetic noise particularly when the cable runs in proximity of the high current and high voltage noise sources.

Therefore, further improvements to the Rogowski coil would be desirable.

### SUMMARY OF THE INVENTION

The embodiments of the present disclosure generally related to a Rogowski integrator kit for electrical measuring.

In some embodiments, the present disclosure provides Rogowski integrator kit. The Rogowski integrator kit includes a Rogowski coil with a first RJ45 socket and an electrical integrator with a second RJ45 socket.

In some other embodiments, the present disclosure provides an electrical integrator with a RJ45 socket which is configured to receive an electrical signal proportional to the rate of change of a current measured by a Rogowski coil and convert the electrical signal to another electrical signal proportional to the current.

These and other features and aspects of the present disclosure will become fully apparent from the following detailed description of exemplary embodiments, the appended claims and the accompanying drawings.

### BRIEF DESCRIPTION OF THE DRAWINGS

FIG. 1 is a schematic diagram of an exemplary Rogowski Integrator Kit for monitoring current for any metered point within a power distribution system, according to some embodiments of the invention.

FIG. 2 is another schematic diagram of an exemplary Rogowski Integrator Kit for monitoring current for any metered point within a power distribution system, according to some embodiments of the invention.

FIG. 3 is a schematic diagram illustrating that a closing unit can be horizontally oriented with the Rogowski coil installed.

FIG. 4 is a schematic diagram illustrating that the closing unit can be vertically oriented with the Rogowski coil installed.

FIG. 5 is a schematic diagram illustrating an exemplary smart grid according to some embodiments of the invention.

FIG. 6 is a schematic diagram illustrating an intelligent electronic device according to some embodiments of the invention.

### DETAIL DESCRIPTIONS OF THE INVENTION

Embodiments of the present disclosure will be described herein with reference to the accompanying drawings. In the following descriptions, well-known functions or constructions are not described in detail to avoid obscuring the present disclosure. The word “exemplary” is used herein to mean “serving as an example.” Any configuration or design described herein as “exemplary” is not to be construed as preferred, or advantageous, over other configurations or designs. Herein the phrase “coupled” is defined as “directly connected to or indirectly connected with” one or more intermediate components. Such intermediate components may include both hardware and software-based components.

It is further noted that, unless otherwise indicated, all functions described herein may be implemented in either software, hardware, or some combination thereof.

It should be recognized that the present disclosure can be performed in numerous ways, including as a process, an apparatus, a system, a method, or a computer-readable medium such as a computer storage medium.

As used herein, intelligent electronic devices (“IEDs”) can be any device that senses electrical parameters and computes data including, but not limited to, Programmable Logic Controllers (“PLCs”), Remote Terminal Units (“RTUs”), electrical power meters, protective relays, fault recorders, phase measurement units, and other devices which are coupled with power distribution networks to control and manage the distribution or consumption of electrical power.

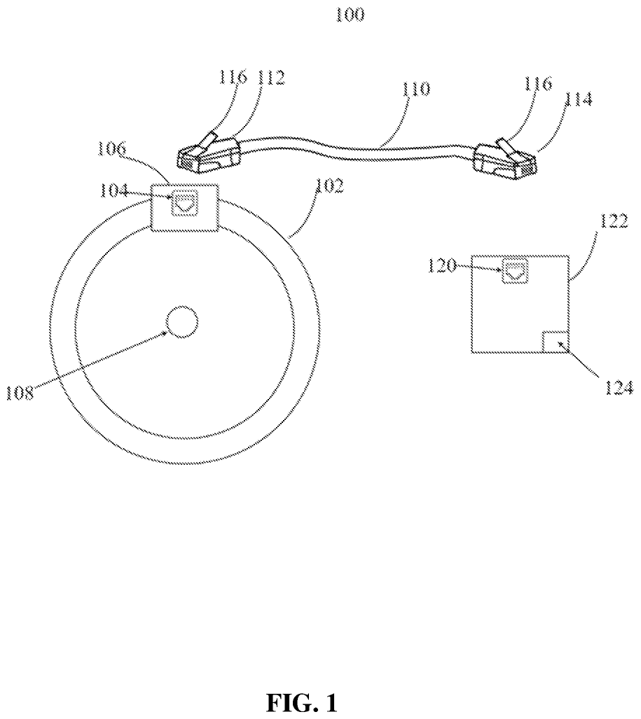

FIG. 1 illustrates a schematic diagram of an exemplary Rogowski Integrator Kit (RIK) 100 for monitoring current for any metered point within a power distribution system according to some embodiments of the invention. The RIK 100 enables the use of Rogowski coils in an IED, such as a power meter, providing a simple and flexible plug-and-play solution for applications with limited physical space or large, irregularly shaped conductors such as busbars.

In FIG. 1, two ends of the Rogowski coil 102 are joined in a closing unit 106. The closing unit 106 includes an RJ45 socket 104 that connects to the Rogowski coil output terminals. When current flows through the conductor 108, the Rogowski coil output terminal produces an electrical signal, such as voltage, that is directly proportional to the change in current.

In some embodiments, the closing unit 106 can incorporate a temperature measurement circuit for determining the operational temperature of the Rogowski coil 102. A thermocouple, for instance, can be utilized to perform this measurement. The thermocouple works by generating a voltage, which is directly proportional to the temperature differential between the junction of two dissimilar metals and a reference temperature, also known as the cold junction. This voltage, being indicative of the temperature, can be interfaced with the RJ45 socket 104. Via the cable 110, this voltage signal can then be relayed to an IED.

In some embodiments, the RJ45 socket 104 is designed to support rugged and highly reliable RJ45 connectors. These connectors are typically 8 positions, 8 connections (8P8C), and are internally shielded to incorporate connections to shielded cables. They also come with various external components that help protect the device in harsh environments.

In some embodiments, the RJ45 socket 104 is compatible with an RJ45 connector that features a tab 116 and only permits insertion in one orientation, preventing incorrect connections. This feature ensures that the operator receives the correct voltage polarity, depending on the direction of current flowing through the coil. When the current is flowing upward, the output voltage has an opposite polarity to that generated by a downward current.

The RIK 100 may include an RJ45 coupler (not shown in FIG. 1) in some embodiments, which is also known as an Ethernet coupler. This plastic or metal connector typically has open ends on both sides, which are usually female ports. It is a more convenient and reliable way to extend the RJ45 cable 110.

The Rogowski coil 102 produces a voltage that is directly proportional to the rate of change (derivative) of the current in the conductor 108. To obtain a signal output 124 that is proportional to the current in the conductor 108, the output of the Rogowski coil 102 is connected to an electrical integrator 122. The integrator 122 is equipped with an RJ45 socket 120 for connection to the Rogowski coil 102. The signal output 124 may connect with an IED, such as a power meter.

An RJ45 cable 110, commonly referred to as an Ethernet cable, is utilized to establish the connection between the Rogowski coil 102 and the integrator 122. The cable 110 is terminated with RJ45 connectors 112 and 114 at either end. RJ45 connector 112 can be inserted into the matching socket 104 on the Rogowski coil 102, while RJ45 connector 114 can be inserted into the RJ45 socket 120 on the integrator 122.

The RJ45 connectors 112 and 114 are designed with metal contacts separated by insulating plastic channels, which ensure a secure and removable connection. The connectors contain 8 pins and 8 wire positions used to handle signals or power and can accommodate 4 twisted wire pairs. In some embodiments, one pair of the 4 twisted wire pairs may be used to transmit the electrical signal proportional to the variation of current in conductor 108 through the RJ45 socket 104.

The RIK 100 utilizes RJ45 cables 110 to connect the Rogowski coil 102 to the electrical integrator 120, and the most used cables are Cat5, Cat6, and Cat7. Despite their different performance metrics, they all feature 8 wires and 4 twisted wire pairs that match the RJ45 connector's 8P8C configuration in the closing unit 106.

One of the significant advantages of using RJ45 cables and connectors in the RIK 100 is that they offer better Electromagnetic Interference (EMI) and Electrostatic Discharge (ESD) protection. Additionally, RJ45 connectors have 8 contacts and 8 wire positions for signals or power, which means they can support 4 twisted wire pairs. The ability to deliver electrical power to connected devices, such as the electrical integrator, is another feature that makes RJ45 connectors a perfect fit for Rogowski coil applications.

The concept of Power over Ethernet (POE) is leveraged in transmitting the measured electrical signals by Rogowski transducer over ethernet using RJ45 connectors and sockets. The RJ45 connectors are arranged in a specific order to ensure each of the various contacts functions correctly, and the color-coded wires must be inserted into the correct pinout locations. Pass-through connectors are available, allowing wires to be fed through and trimmed during the crimping process for easier alignment.

The output signal of the Rogowski coil is a limited AC voltage proportional to the rate of current change and is usually connected to high burden IEDs with low-value currents and voltages. Even after amplification by the electrical integrator, the output power is still low enough to be transmitted over ethernet cables and switches. IEEE standard 802.3af governs PoE and offers up to 15.4 W power transmission. This makes the power transmission through the ethernet cable feasible, even after voltage amplification at the electrical integrator.

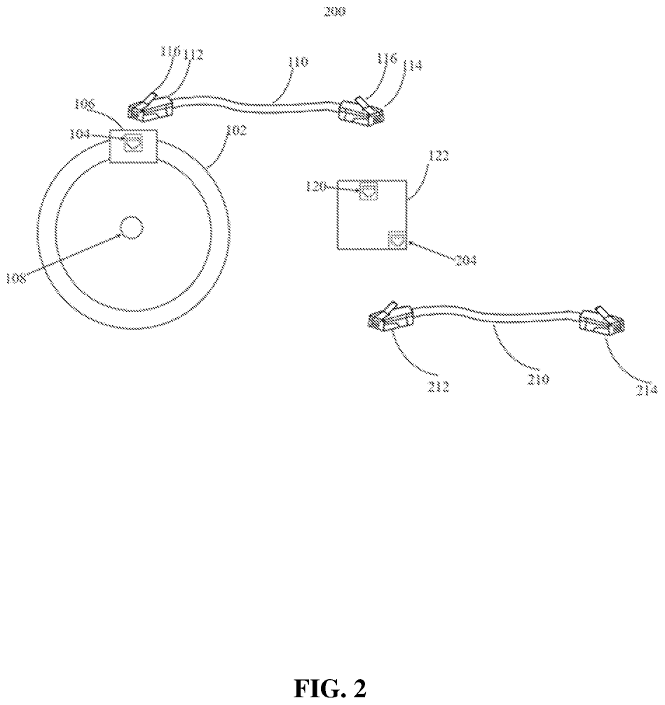

FIG. 2 depicts a schematic diagram of an exemplary Rogowski Integrator Kit (RIK) 200 designed to monitor current for any metered point within a power distribution system, according to some embodiments of the invention. The RIK 200 shares similarities with the RIK 100, and for brevity, please refer to the above description with the same reference numbers used for corresponding elements.

In addition to the features of the RIK 100, FIG. 2 shows an extra RJ45 socket 204 based on FIG. 1, which connects to the signal output 124 in the integrator 122. An RJ45 cable 210, featuring an RJ45 connector 212 and an RJ45 connector 214, connects the electrical integrator 122 to an IED, such as a power meter. To establish a connection, RJ45 connector 212 is plugged into RJ45 socket 204, while RJ45 connector 214 is inserted into an embedded RJ45 socket on the IED.

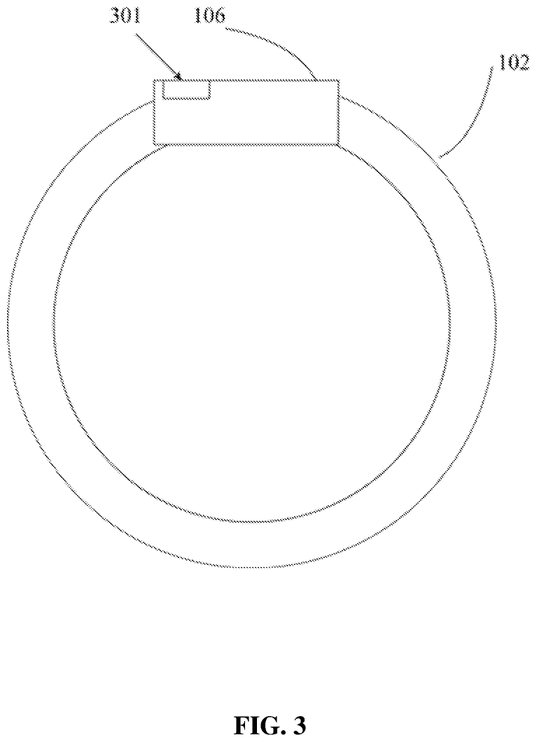

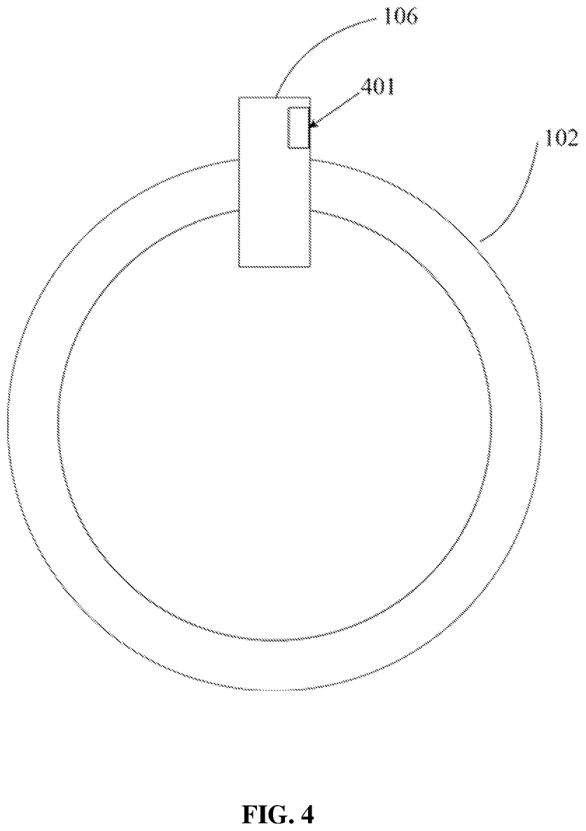

The installation of a fixed closing unit for the Rogowski coil in the field can be challenging due to limited space constraints. However, this issue is addressed by the present disclosure through the introduction of a versatile closing unit that can be mounted horizontally or vertically, allowing for various installation options such as mounting on a panel, surface, or through a hole. As shown in FIG. 3, the closing unit 106 can be horizontally oriented with the Rogowski coil 102 installed, and an RJ45 socket 301 embedded within the closing unit 106 for easy connectivity. As shown in FIG. 4, the closing unit 106 can be vertically oriented with the Rogowski coil 102 installed, and an RJ45 socket 401 embedded within the closing unit 106 for easy connectivity.

In conventional smart grid systems, the output signal of a Rogowski coil cannot be utilized directly, limiting its effectiveness. The main objective of a smart grid is to leverage digital communication technology to detect and react to local changes in electricity usage. To address this issue, the present invention proposes equipping a Rogowski coil with an RJ45 socket, which enables the measured signal to be transmitted as a data signal to a remote terminal unit (RTU). The RTU is a remote device that monitors and reports events occurring at a remote site.

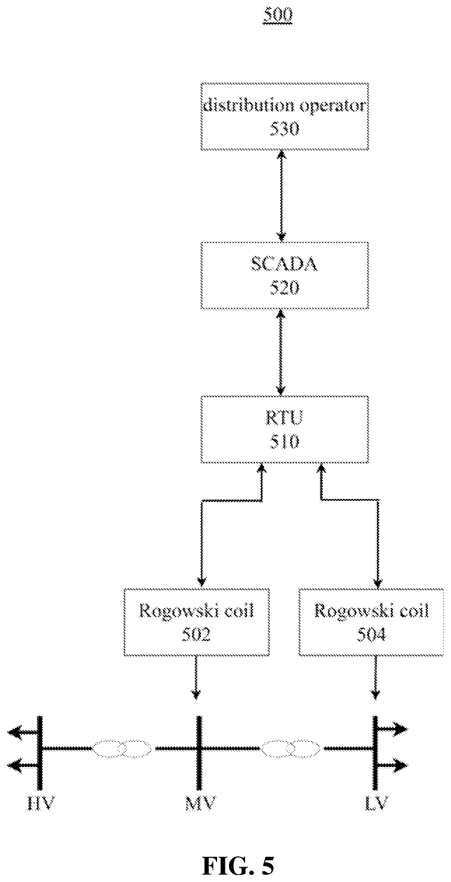

FIG. 5 illustrates an exemplary smart grid according to some embodiments of the invention. The smart grid 500 is an advanced electricity network that employs digital and other advanced technologies to monitor and manage the transportation of electricity from all generation sources to meet the varying electricity demands of end users. Smart grids coordinate the needs and capabilities of all generators, grid operators, end users and electricity market stakeholders to operate all parts of the system as efficiently as possible, minimizing costs and environmental impacts while maximizing system reliability, resilience, flexibility and stability.

Rogowski coils 502 and 504, equipped with RJ45 sockets, monitor the current changes of metering points. The monitoring data is then transferred to the RTU 510 via a RJ45 cable, which is inserted into the RJ45 socket. The RTU 510 then transmits the data to the SCADA (Supervisory Control and Data Acquisition) 520. The SCADA 520 is a computer-based system for gathering and analyzing real-time data to monitor and control equipment that deals with critical and time-sensitive materials or events. Finally, a distribution operator 530 observes the events reported by the SCADA 520 and takes appropriate actions.

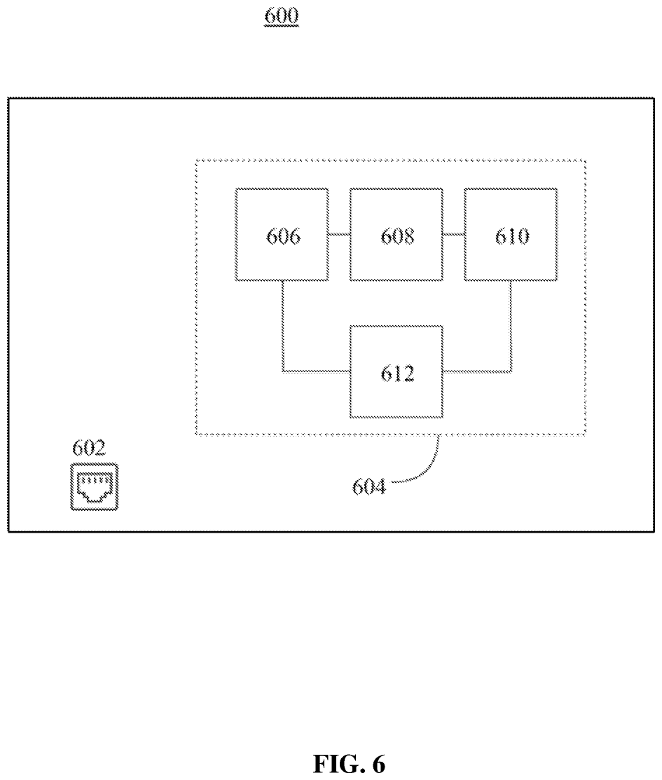

In FIG. 2, RJ45 connector 214 may be connected to an IED to transfer a current measured by Rogowski coil 102. The IED may have both an RJ45 socket for receiving Ethernet data and another RJ45 socket for receiving a signal representing the current measured by Rogowski 102. The user may not be able to tell the difference between these two RJ45 sockets because they have the same appearance. It is possible for the user to insert the RJ45 connector into the wrong RJ45 socket. In order to solve this problem, this application proposes an intelligent electronic device that can automatically identify the type of input and transmit different types of input to different processing circuits. Referring to FIG. 6, which illustrate such an intelligent electronic device 600.

In FIG. 2, RJ45 connector 214 is configured to establish a connection with an intelligent electronic device (IED) for the purpose of transmitting current measurements obtained through Rogowski coil 102. The IED is equipped with dual RJ45 sockets; the first socket is designated for the reception of Ethernet data, while the second socket is intended for the reception of signals indicative of the current measured by Rogowski coil 102. Owing to the identical physical attributes of these RJ45 sockets, users may inadvertently establish connections with the incorrect socket. To circumvent this issue, the present invention introduces an intelligent electronic device (IED), designated as 600 in FIG. 6, endowed with the capability to autonomously discern input types and accordingly route these inputs to the respective processing circuits.

In FIG. 6, the IED features an RJ45 socket, labeled as 602, adept at concurrently receiving Ethernet data and a signal indicative of the current in a conductor. Incorporated within the device is circuit 604, which facilitates the routing of the Ethernet data signal to the data processing subsystem, and the measured signal to the measurement subsystem.

Circuit 604 includes several integral components: a signal detection component (606), a signal conditioning component (608), a signal routing component (610), and control logic (612).

The signal detection component 606 is interfaced with RJ45 socket 602 and is responsible for receiving inputs which may include Ethernet signals and measured signals. The component employs both high-pass and low-pass filters in parallel to segregate the signals based on their frequencies. The high-pass filter is calibrated to permit passage to high-frequency Ethernet signals, whereas the low-pass filter is configured to allow only the low-frequency signals from the Rogowski coil.

The signal conditioning component 608 plays a pivotal role in ensuring that the acquired signals are amenable to processing by conforming to a specific amplitude and phase range. This involves interfacing the output of the low-pass filter with a voltage follower, typically realized using an operational amplifier, which serves to buffer the signal.

The signal routing component 610 is tasked with the accurate routing of the conditioned signals to the designated subsystems. This component may interface either directly with the signal detection component 606 or indirectly through the signal conditioning component 608. The routing is executed through the deployment of electronic switches or relays. Specifically, the switch associated with the high-pass filter output is regulated to route Ethernet signals to the data processing subsystem, while the switch associated with the low-pass filter output is regulated to route Rogowski coil signals to the measurement subsystem.

The control logic 612 operates in tandem with the signal detection component 606 to exercise control over the state of switches within the signal routing component 610. The implementation of control logic can be realized through the employment of discrete logic gates or a microcontroller, and it should be adept at handling the specifications of Rogowski coil signals with precision and reliability.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The following is claimed:

1. A Rogowski integrator kit comprising:
a Rogowski coil with a first RJ45 socket; and
an electrical integrator with a second RJ45 socket.

2. The Rogowski integrator kit of claim 1, wherein the first RJ45 socket is configured to provide a first electrical signal proportional to the rate of change of a current through a conductor, the second RJ45 socket is configured to receive the first electrical signal and the electrical integrator is configured to convert the first electrical signal to a second electrical signal that is proportional to the current.

3. The Rogowski integrator kit of claim 1 further comprising a RJ45 coupler.

4. The Rogowski integrator kit of claim 2 further comprising a RJ45 cable with RJ45 connectors which is used to connect the first RJ45 socket and the second RJ45 socket.

5. The Rogowski integrator kit of claim 2, wherein the electrical integrator includes a third RJ45 socket providing the second electrical signal to an external device.

6. The Rogowski integrator kit of claim 2, wherein the first RJ45 socket is embedded in a closing unit where two ends of the Rogowski coil are joined.

7. The Rogowski integrator kit of claim 6, wherein the closing unit can be installed with the Rogowski coil in at least one of a vertical orientation and a horizontal orientation to adapt to specific installation constraints.

8. A Rogowski coil with a fourth RJ45 socket which is configured to provide an electrical signal proportional to the rate of change of a current through a conductor wrapped around the Rogowski coil.

9. The Rogowski coil of claim 8, wherein the fourth RJ45 socket is embedded in a closing unit where two ends of the Rogowski coil are joined.

10. The Rogowski coil of claim 9, wherein the closing unit can be installed with the Rogowski coil in at least one of a vertical orientation and a horizontal orientation to adapt to specific installation constraints.

11. The Rogowski coil of claim 9, wherein the fourth RJ45 socket is further configured to provide an electrical signal proportional to the operation temperature of the Rogowski coil.

12. An electrical integrator with a fifth RJ45 socket which is configured to receive a third electrical signal proportional to the rate of change of a current measured by a Rogowski coil and convert the third electrical signal to a fourth electrical signal proportional to the current.

13. The electrical integrator of claim 12, wherein the electrical integrator includes a sixth RJ45 socket providing the fourth electrical signal to an external device.

14. An improved smart grid system comprising:
a Rogowski coil that is equipped with a seventh RJ45 socket for data communication; and
a remote terminal unit that connects with the Rogowski coil using a RJ45 cable, which is inserted into the seventh RJ45 socket for secure and reliable transmission of data.
